(19) United States
(12) Patent Application Publication
(10) Pub. No.: US 2018/0080995 A1
(43) Pub. Date: Mar. 22, 2018

(54) NOTIFICATION SYSTEM AND METHOD FOR PROVIDING REMAINING RUNNING TIME OF A BATTERY

(71) Applicant: Faraday&Future Inc., Gardena, CA (US)

(72) Inventor: Garrett David HEINEN, San Luis Obispo, CA (US)

(73) Assignee: Faraday&Future Inc., Gardena, CA (US)

(21) Appl. No.: 15/270,025

(22) Filed: Sep. 20, 2016

(51) Int. Cl. G01R 31/36; B60L 11/18; G07C 5/08

(52) U.S. Cl. CPC G01R 31/3679; G07C 5/0816; B60L 11/1861

(57) ABSTRACT

A notification method and system for providing notification regarding remaining time of a battery are disclosed. According to certain embodiments, the method may include predicting an ambient temperature of the battery. The method may also include determining a power demand for the battery. The method may also include determining a state of health (SoH) of the battery. The method may also include predicting a remaining time for a state of charge (SoC) of the battery to reach a predetermined level, based on the ambient temperature, the power demand, and the SoH. The method may further include providing a notification regarding the remaining time.

### TECHNICAL FIELD

The present disclosure relates generally to a notification system and method for providing remaining running time of a battery, and more particularly, to a system and method for determining and providing notification regarding the remaining time for the state of charge (SoC) of a battery to reach a predetermined level.

### BACKGROUND

Battery is an essential part of a vehicle. In particular, the battery serves as the only power source for an electric vehicle and a hybrid vehicle working in the electric mode. Even for conventional vehicles powered by combustion engines, batteries must be relied upon to keep the lights and other on-board electronics working when the vehicle ignition is turned off and to provide cranking power to start the vehicle. Thus, it is desirable for a user to stay informed of the remaining running time of a vehicle battery, so as to timely recharge or replace the battery.

Currently, many vehicles notify their users about the amount of energy left in a battery by displaying the state of charge (SoC) of the battery. The SoC is the equivalent of a fuel gauge for the battery, with “100%” indicating the battery is in a fully charged state and “0%” indicating the battery is empty. Some vehicles also provide the state of energy (SoE) of the vehicles, usually in the form of a mile range that the vehicles are able to reach.

However, neither the SoC nor the SoE is an intuitive indicator for a user to understand how much longer the battery can continue operating under the current load. This is because, unlike gasoline, the battery discharges current all the time. Even when the vehicle is turned off, the energy of the battery is continuously drained due to self-discharge and power demand by the vehicle monitor system (e.g., vehicle security and/or tracking systems). That is, a parked vehicle may not consume fuels but still consume electrical energy from the battery. Therefore, more useful notifications are needed to tell a user how long she can keep the car in the current status before having to recharge or replace the battery.

For example, when a user needs to travel oversea and thus has to park her car in a garage for an extended period, she may want to be constantly reminded, both before and during the trip, how much longer she can leave the battery uncharged without facing a dead battery or having not enough capacity to drive to a charging station when she needs to start the car again.

The disclosed notification system and method are directed to mitigating or overcoming one or more of the problems set forth above and/or other problems in the prior art.

### SUMMARY

One aspect of the present disclosure is directed to a notification method for a battery. The method may include predicting an ambient temperature of the battery. The method may also include determining a power demand for the battery. The method may also include determining a state of health (SoH) of the battery. The method may also include predicting a remaining time for a state of charge (SoC) of the battery to reach a predetermined level, based on the ambient temperature, the power demand, and the SoH. The method may further include providing a notification regarding the remaining time.

Another aspect of the present disclosure is directed to a notification system of for a battery. The system may include a memory storing instructions. The system may also include a processor configured to execute the instructions to: predict an ambient temperature of the battery; determine a power demand for the battery; determine a state of health (SoH) of the battery; predict a remaining time for a state of charge (SoC) of the battery to reach a predetermined level, based on the ambient temperature, the power demand, and the SoH; and provide the notification regarding the remaining time.

Yet another aspect of the present disclosure is directed to a vehicle. The vehicle may include a battery. The vehicle may also include a battery management system configured to determine a state of charge (SoC) and a state of health (SoH) of the battery. The vehicle may further include a controller configured to: predict an ambient temperature of the battery; determine power required by the vehicle; predict a remaining time for the SoC of the battery to reach a predetermined level, based on the ambient temperature, the power required by the vehicle, and the SoH; and provide the notification regarding the remaining time.

### BRIEF DESCRIPTION OF THE DRAWINGS

FIG. 1 is a block diagram of a notification system for remaining time of a battery, according to an exemplary embodiment;

FIG. 2 is a schematic diagram illustrating an implementation of remaining time calculator 100 of the system shown in FIG. 1, according to an exemplary embodiment;

FIG. 3 is a schematic diagram illustrating a process performed by remaining time calculator 100 shown in FIG. 2, according to an exemplary embodiment;

FIG. 4 is a flowchart of a notification method for remaining time of a battery, according to an exemplary embodiment;

FIG. 5 is a schematic diagram illustrating an implementation of step 404 of the method shown in FIG. 4, according to an exemplary embodiment;

FIG. 6 is a schematic diagram illustrating an implementation of step 406 of the method shown in FIG. 4, according to an exemplary embodiment; and

FIG. 7 is a schematic diagram illustrating an implementation of steps 408 and 410 of the method shown in FIG. 4, according to an exemplary embodiment.

### DETAILED DESCRIPTION

This disclosure is generally directed to a notification system and method for providing remaining running time of a battery. For illustrative purpose only, the principles of the present disclosure are described in connection with a battery used in a vehicle. Nevertheless, those skilled in the art will recognize that the principles of the present disclosure may be applied in any types of device or machine at least partially powered by a battery. For example, these devices or machines include but are not limited to mobile phones, portable electronics, wearable devices (e.g., watch, wristband, etc.), medical devices (e.g., blood pressure monitor, emergency defibrillator, etc.), flight monitors (also known as “black box”) used in aircrafts.

The vehicle in the disclosed embodiments may be an electric vehicle, a fuel cell vehicle, a hybrid vehicle, or a conventional internal combustion engine vehicle. The vehicle may have any body style, such as a sports car, a coupe, a sedan, a pick-up truck, a station wagon, a sports utility vehicle (SUV), a minivan, or a conversion van. The vehicle may be configured to be operated by an operator occupying the vehicle, remotely controlled, and/or autonomous.

The vehicle may use one or more batteries to store and supply energy. For example, in the case of an electric vehicle or a hybrid vehicle, the vehicle may include one or more high-voltage battery packs that output high-voltage direct current (DC), e.g., 400V, to an electric drive system. The vehicle may also include one or more 12V batteries used to supply 12V DC voltage for driving the 12V loads onboard, such as power door/window, radio, lighting, heating, ventilation, and air conditioning (HVAC) systems, etc.

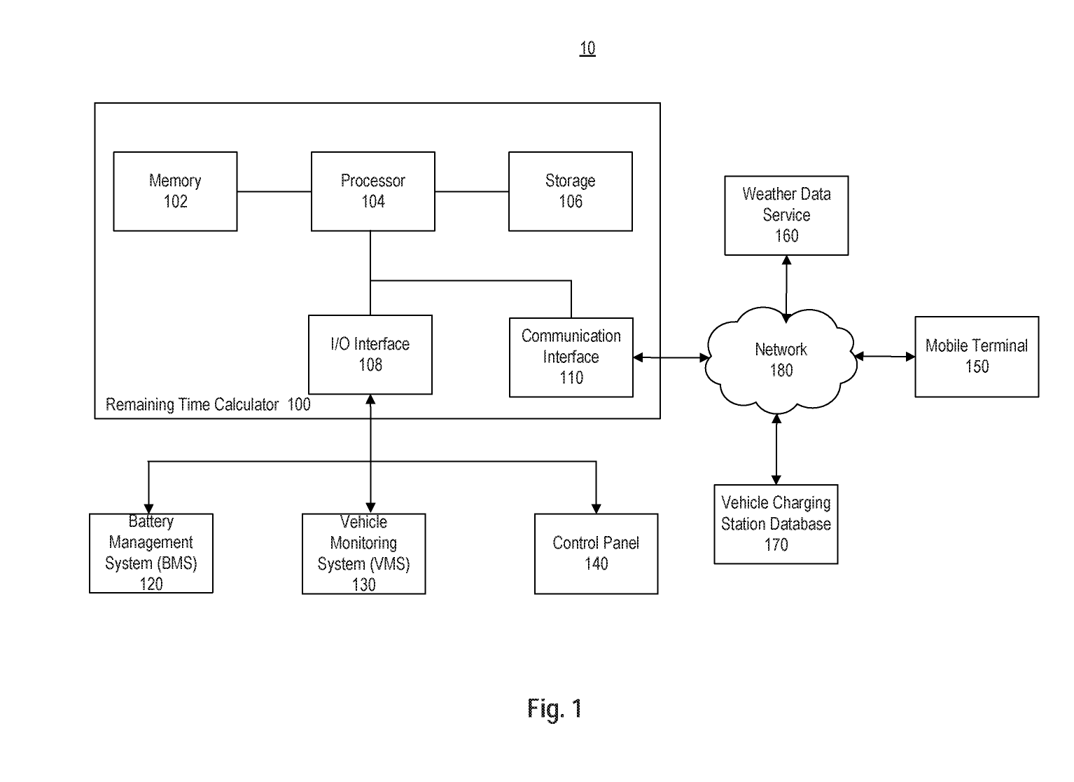

FIG. 1 is a block diagram of a notification system 10 for remaining time of a battery, according to an exemplary embodiment. For example, system 10 may be employed by the above-described vehicle to provide notification of the remaining time of a battery of the vehicle. Referring to FIG. 1, system 10 may include one or more of a remaining time calculator 100, a battery management system (BMS) 120, a vehicle monitoring system (VMS) 130, a control panel 140, a mobile terminal 150, a weather data service 160, a vehicle charging station database 170, and a network 180.

Remaining time calculator 100 may be configured to determine the remaining time of the battery and generate a notification regarding the remaining time. In some embodiments, remaining time calculator 100 may be part of the vehicle's on-board computer system. With continued reference to FIG. 1, remaining time calculator 100 may include, among other things, a memory 102, a processor 104, a storage 106, an input/output (I/O) interface 108, and a communication interface 110. At least some of these components of remaining time calculator 100 may be configured to transfer data and send or receive instructions between or among each other.

Processor 104 may include any appropriate type of general-purpose or special-purpose microprocessor, digital signal processor, or microcontroller. Processor 104 may be configured as a separate processor module dedicated to provide a notification about the remaining time of the battery. Alternatively, processor 104 may be configured as a shared processor module for performing other functions unrelated to providing the notification.

Processor 104 may be configured to receive data and/or signals from components of system 10 and process the data and/or signals to determine one or more conditions related to the battery. For example, processor 104 may receive information regarding the state of charge (SoC) and state of health (SoH) from BMS 120 via, for example, I/O interface 108. Processor 104 may also access weather data service 160 via, for example, communication interface 110, to collect weather data of the area where the vehicle is used and/or parked. Moreover, after determining the remaining time of the battery, processor 104 may further transmit the determined remaining time to control panel 140 and/or mobile terminal 150 for presentation to the user.

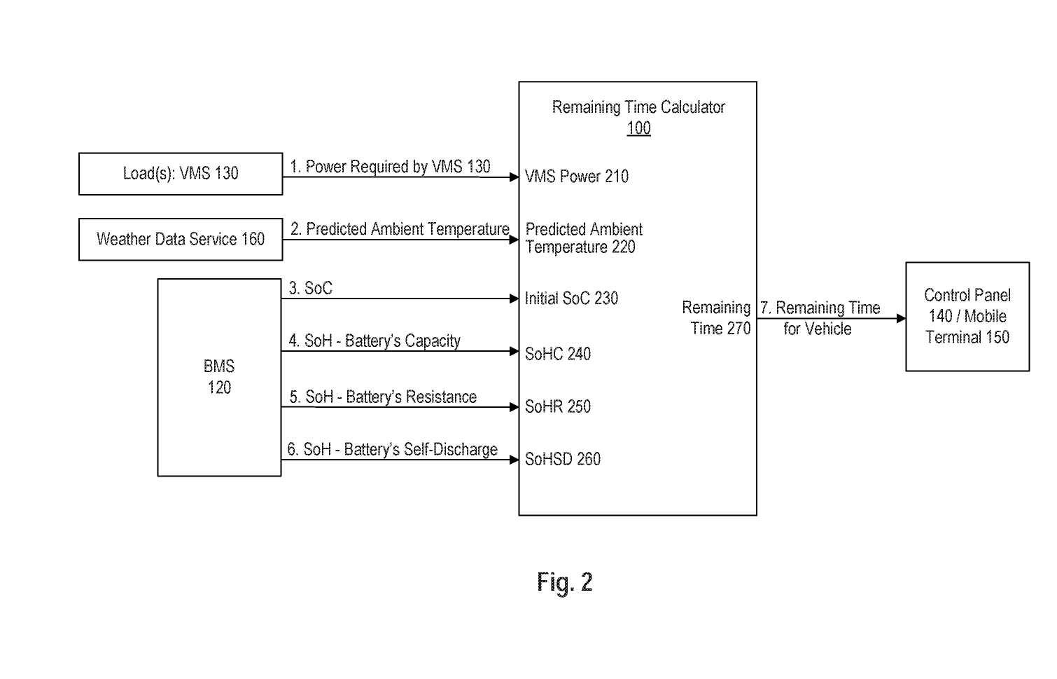

Processor 104 may execute computer instructions (e.g., program codes) stored in memory 102 and/or storage 106, and may perform functions in accordance with exemplary techniques described in this disclosure. More exemplary functions of processor 104 will be described later in relation to FIGS. 2-7.

Memory 102 and storage 106 may include any appropriate type of mass storage provided to store any type of information that processor 104 may need to operate. Memory 102 and storage 106 may be a volatile or non-volatile, magnetic, semiconductor, tape, optical, removable, non-removable, or other type of storage device or tangible (i.e., non-transitory) computer-readable medium including, but not limited to, a ROM, a flash memory, a dynamic RAM, and a static RAM. Memory 102 and/or storage 106 may be configured to store one or more computer programs that may be executed by processor 104 to perform the disclosed method for providing notification of the remaining time of the battery. For example, memory 102 and/or storage 106 may be configured to store program(s) that may be executed by processor 104 to predict the remaining time based on the battery's SoC, SoH, load condition, future ambient temperature, etc.

Memory 102 and/or storage 106 may be further configured to store information and data used by processor 104. For instance, memory 102 and/or storage 106 may be configured to store lookup tables indicating the dependence of the battery's self-discharge current, internal resistance, and/or open-circuit voltage on various factors, such as the SoC, the ambient temperature, etc.

I/O interface 108 may be configured to facilitate the communication between remaining time calculator 100 and other components of system 10. For example, I/O interface 108 may receive a signal generated by BMS 120 that indicates the SoC and/or SoH of the battery, and transmit the signal to processor 104 for further processing. I/O interface 108 may also receive a signal generated by VMS 130 that indicates the power required by the VMS 130, and transmit the signal to processor 104 for further processing. I/O interface 108 may further output commands to control panel 140 and/or mobile terminal 150 for displaying the remaining time of the battery and reminding the user about recharging the battery.

Communication interface 110 may be configured to communicate with mobile terminal 150, weather data service 160, and vehicle charging station database 170 via network 180. Network 180 may be any type of wired or wireless network that may allow transmitting and receiving data. For example, network 180 may be a wired network, a local wireless network (e.g., Bluetooth™, WiFi, near field communications (NFC), etc.), a cellular network, an Internet, or the like, or a combination thereof. Other known communication methods which provide a medium for transmitting data are also contemplated.

BMS 120 may be configured to manage the usage and charging of the battery pack in a safe and reliable manner In particular, BMS 120 may constantly monitor the state of charge (SoC) of the battery. The term “State of Charge,” as used in the present disclosure, refers to the remaining charge in the battery as compared to the amount of charge when the battery is fully charged. Therefore, the SoC may be expressed as a percentage of the fully charge state. In the disclosed embodiments, BMS 120 may monitor the output voltage of the battery, voltages of individual cells in the battery pack, current in and/or out of the battery pack, etc., to determine the SoC. BMS 120 may send information regarding the SoC to remaining time calculator 100 for further processing.

BMS 120 may also be configured to monitor the state of health (SoH) of the battery. The term “State of Health,” as used in the present disclosure, refers to one of more of a capacity of the battery, an internal resistance of the battery, self-discharge characteristics of the battery, and/or cell temperature of the battery. The capacity of the battery is the amount of charge the battery can deliver at the rated voltage and a specified temperature, e.g., 20° C., and may be expressed in the unit of amp-hour (A·h). The capacity may be used to determine the amount of time that the battery can sustain at a given current drawn from the battery, according to any methods known in the art, e.g., Peukert's law. These methods of using a battery's capacity to determine the battery's discharge time are incorporated in the present disclosure by reference, which will not be elaborated. The self-discharge characteristics indicate the dissipation rate of the charge in the battery as a function of various factors, such as an ambient temperature and SoC of the battery, when the battery is not connected to a load. For example, the self-discharge characteristics may be expressed as a self-discharge current when the battery does not supply power to any load.

SoH is used to describe the condition of the battery relative to the ideal or rated condition when the battery is new. Generally, the SoH deteriorates as the battery ages. For example, with the aging of the battery, the capacity of the battery decreases, while the internal resistance of the battery and the degree of the self-discharge rise. Similar to the SoC, BMS 120 may constantly monitor the SoH and send information regarding the SoH to remaining time calculator 100 for further processing.

VMS 130 may be configured to monitor the state of the vehicle. For example, VMS 130 may include a vehicle security system configured to generate an alarm when an unauthorized person is detected to have broken into the vehicle. As another example, VMS 130 may include a GPS device to report and track the location of the vehicle. In practice, VMS 130 continues to operate even after the vehicle is turned off, and thus draws power from the battery all the time. In one embodiment, the power required by VMS 130 fluctuates depending on the vehicle's operation mode and thus VMS 130 may be configured to periodically send a signal to processors 104, updating in real time the power required by VMS 130.

Weather data service 160 may be a server generating and/or storing weather information of the area where the vehicle is located. For example, weather data service 160 may be a cloud server that can be remotely accessed by processor 104 via network 180. The cloud server may include one or more cloud-based processors configured to process and generate the weather information. The cloud server may also include one or more cloud-based storage devices for storing the weather information. Based on the weather information, processor 104 may determine an ambient temperature of the battery in the future. In one embodiment, the weather information may include weather forecast for a specified time period in the future, such as hourly weather forecast for the next day or week. For example, weather data service 160 may be provided by a government agency such as National Weather Service (www.weather.com), or a commercial weather forecasting service such as AccuWeather (www.accuweather.com). In some embodiment, processor 104 may use the forecasted air temperature as the future ambient temperature of the battery, and predict the remaining time of the battery based on the future ambient temperature.

The weather forecast often covers a relatively short time period in the future. However, occasionally processor 104 may need to know the future ambient temperature for a longer time span, for example, one or three months. Accordingly, in some embodiments, weather data service 160 may also provide historical weather data of the area where the vehicle is located. The historical weather data may include the past (e.g., past five years′) daily weather conditions in terms of temperature, atmospheric pressure, wind, moisture, cloud condition, precipitation, etc. Processor 140 may use a meteorology model to estimate the future weather condition based on the historical weather data. Processor 140 may further use a temperature model to predict the ambient temperature based on the estimated weather condition.

Vehicle charging station database 170 may store information (e.g., location information, price, etc.) associated with vehicle charging stations. Vehicle charging station database 170 may be stored in a server operated by the manufacturer of the vehicle, a vehicle service provider, a government agency regulating the charging stations, etc. Vehicle charging station database 170 may be constantly updated to reflect the change of existing charging stations and addition of new charging stations. In exemplary embodiments, processor 104 may determine whether the remaining energy in the battery is enough for the vehicle to reach a charging station near the vehicle. For example, as described in more detail below, processor 104 may access vehicle charging station database 170 to obtain a map of the charging stations in a vicinity of the vehicle and determine the minimum battery energy needed to reach a nearby charging station.

As described above, processor 104 may present notification of the remaining time of the battery via control panel 140 and/or mobile terminal 150. Control panel 140 may be housed in the dashboard of the vehicle. Control panel 140 may include a display panel configured to output texts, graphs, images, videos, and/or other types of visual information. The display panel may include a Liquid Crystal Display (LCD), a Light Emitting Diode (LED) display, a plasma display, or any other type of display. The display panel may also provide a Graphical User Interface (GUI) or a touchscreen for user input. Other types of input devices, such as keyboard, rotation knob, trackball, etc., may also be provided with control panel. In addition, control panel 140 may include a speaker and/or microphone configured to output and/or receive audio information. As described in more detail below, control panel 140 may present the notification about the remaining time of the battery as a visual and/or audio alert. Control panel 140 may also receive the user's manual input, voice command, and/or haptic command to adjust the settings of remaining time calculator 100.

Mobile device 150 may be a handheld device, such as a tablet computer, a laptop computer, a smart phone with computing ability, a remote controller, a personal digital assistant (PDA), a wearable device (e.g., a smart watch, a smart wrist band, Google Glass™, etc.), and/or affiliated components. Similar to control panel 140, mobile device 150 may output the notification generated by processor 104 to a user, and/or receive user input to adjust the settings of remaining time calculator 100. In the disclosed embodiments, mobile device 150 may wirelessly communicate with remaining time calculator 100 via network 180. Accordingly, when a user is not in the vehicle, the user may use mobile terminal 150 to receive the notification about the remaining time of the battery and/or set a schedule for reminding the user of charging the vehicle.

FIG. 2 is a schematic diagram illustrating a process performed by remaining time calculator 100 to predict the remaining time for a battery, according to an exemplary embodiment. Referring to FIG. 2, remaining time calculator 100 may predict the remaining time based on the power required by the load(s) connected to the battery and the self-discharge characteristics of the battery. Specifically, the input of remaining time calculator 100 may include one or more of: the power required by the load(s), the predicted ambient temperature of the battery, initial SoC of the battery, and SoH of the battery.

Since VMS 130 is always running, the power demand of the load(s) at least includes the power required by VMS 130 (hereinafter referred to as “VMS power 210”), whether the vehicle is turned on or off. In one embodiment, remaining time calculator 100 may use the rated power of VMS 130 as VMS power 210. In another embodiment, VMS power 210 may be periodically reported by VMS 130 to remaining time calculator 100. In yet another embodiment, an ammeter may be used to measure the electric current drawing by VMS 130 in real time, and remaining time calculator 100 may calculate VMS power 210 based on the measured current and the rated voltage of VMS 130. When the vehicle is turned on, the power required by the load(s) may additionally include power required by other devices and systems in the vehicle, including the electric motors, advanced driver assistance system (ADAS), in-vehicle infotainment system, etc.

For illustrative purpose only, the following description assumes VMS 130 is the only load drawing power from the battery, i.e., the vehicle is turned off. However, as described above, the disclosed systems and methods are intended to be applicable to any vehicle state.

The self-discharge characteristics of the battery are affected by the ambient temperature of the battery. Accordingly, remaining time calculator 100 may also predict the ambient temperature of the battery (hereinafter referred to as “predicted ambient temperature 220”) for a specified period of time based on the weather data retrieved from weather data service 160. The weather data describes the weather condition in the area where the vehicle is intended to be used and/or parked. When the weather data is the weather forecast for the specified period of time, remaining time calculator 100 may directly use the forecasted air temperature as predicted ambient temperature 220 of the battery. When only the historical weather data is available, remaining time calculator 100 may predict the ambient temperature based on the historical weather data.

The initial SoC (hereinafter referred to as “initial SoC 230”) and the SoH may be determined and reported to remaining time calculator 100 by BMS 120. The SoH may include information about the capacity, internal resistance, and self-discharge current of the battery (hereinafter referred to as “SoHC 240,” “SoHR 250,” and “SoHSD 260,” respectively). Here, both the internal resistance and the self-discharge current of the battery are functions of the ambient temperature and SoC of the battery. Thus, the input SoHR 250 and SoHSD 260 may be specified by the ambient temperature and SoC under which they are determined.

Based on the above input parameters, remaining time calculator 100 may predict the electric current drawn from the battery over time, and then further predict the remaining time (hereinafter referred to as “remaining time 7”) for the SoC to decrease to a predetermined level. The predetermined level of SoC may be a default level set by the manufacturer of the vehicle, e.g., 0%. The predetermined level of SoC may also be any level set by a user of the vehicle.

Remaining time calculator 100 may transmit a notification of the predicted remaining time to control panel 140 and/or mobile terminal 150 for presentation to the user. Besides indicating the remaining time, the notification may also include an alert as to whether the remaining time is enough for the vehicle to reach a nearby charging station. Consistent with the disclosed embodiments, remaining time calculator 100 may determine the remaining time and generate the notifications periodically (e.g., once a day) or upon the user's request. Moreover, certain conditions may be preset by the user or the manufacturer of the vehicle, such that remaining time calculator 100 may generate the notification once the condition is met. This condition may include but is not limited to: a user-specified SoC (e.g., 20%) is reached; the remaining time is approaching a minimum level required by the vehicle to reach a nearby charging station; and/or the remaining time is no longer enough for the vehicle to reach any charging station and a remedial measure, e.g., a towing truck or charging truck, is needed.

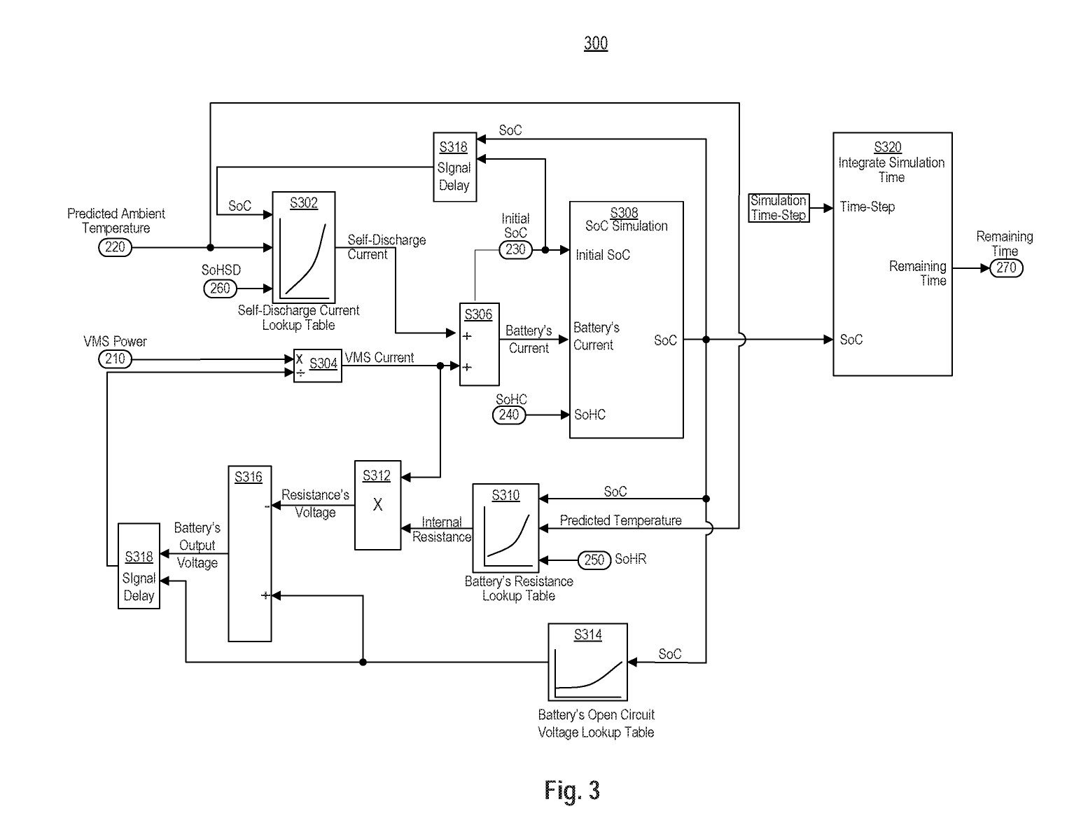

Next, a detailed iterative process for predicting the remaining time will be described. FIG. 3 is a schematic diagram illustrating a remaining-time prediction process 300 performed by remaining time calculator 100, according to an exemplary embodiment. Referring to FIG. 3, remaining time calculator 100 may perform process 300 in multiple time-steps. The time-step may be a constant, or a variable that is changed randomly or deliberately as process 300 proceeds.

Referring to step S302 of FIG. 3, in each time-step, remaining time calculator 100 may determine the self-discharge current of the battery based on predicted ambient temperature 220 in the current time-step, SoHSD 260, and the SoC estimated in the previous time-step (or initial SoC 230 if the current time-step is the first time-step of process 300). As described above, input SoHSD 260 may be given under an ambient temperature and/or SoC that are different from the ambient temperature and SoC in the current time-step. Accordingly, a self-discharge current lookup table may be used to determine the self-discharge current in the current time-step. The self-discharge current lookup table represents the self-discharge current as a function of ambient temperature and SoC. The self-discharge current lookup table, and other lookup tables used in the disclosed embodiments, may be provided by the manufacturer of the battery, or may be created by the manufacturer of the vehicle based on testing data. Remaining time calculator 100 may identify from the self-discharge current lookup table an electric current that correspond to predicted ambient temperature 220 and SoC in the current time-step, and treat the identified current as the self-discharge current in the current time-step.

In step S304, remaining time calculator 100 may compute the electric current of VMS 130 for the current time-step based on input VMS power 210 and the battery's output voltage estimated in the previous time-step (or the battery's open circuit voltage if the current time-step is the first time-step of process 300). The battery's output voltage is the load voltage, or the voltage applied on VMS 130 if VMS 130 is the only load. Remaining time calculator 100 may compute the current of VMS 130 according to:

I_{VMS}=P_{VMS}/Vₒᵤₜ Eq. 1

where I_{VMS}, P_{VMS}, and Vₒᵤₜ are used to denote respectively the electric current of VMS 130, VMS power 210, and the battery's output voltage.

In step S306, remaining time calculator 100 may compute the current flown out of the battery based on the self-discharge current determined in step S302 and the electric current of VMS 130 determined in step S304. This process may be expressed as:

I_{battery}=I_{SD}+I_{VMS} Eq. 2

where I_{battery} and I_{SD} are used to denote respectively the electric current flown out of the battery and the battery's self-discharge current in the current time-step.

As illustrated by step S308, remaining time calculator 100 may run an iterative process to predict the change of the SoC over time. Using initial SoC 230 and SoHC 240 as the initial condition of the battery, techniques like Kalman filter, extended Kalman filter, Luenberger's state estimator, Particle filter, Bayesian Framework, etc., may be employed to predict how the SoC changes from initial SoC 230 to a predetermined level of SoC, e.g., 0%. At each iteration, i.e., time-step, of process 300, an updated SoC at the end of the time-step may be generated.

The updated SoC may be used to update other parameters of the battery. In step S310, remaining time calculator 100 may determine the battery's internal resistance at the current time-step based on predicted ambient temperature 220 at the current time-step, input SoHR 250, and the updated SoC. Similar to the process described in step S302, remaining time calculator 100 may use the battery's resistance lookup table to determine the internal resistance at the current time-step.

Moving to step S312, remaining time calculator 100 may compute the voltage across the internal resistance based on the internal resistance determined in step S310 and the electric current of VMS 130 determined in step 204. Remaining time calculator 100 may compute the voltage across the internal resistance according to:

Vᵢₙₜ=I_{VMS}·Rᵢₙₜ Eq. 3

where Vᵢₙₜ and Rᵢₙₜ are used to denote respectively the voltage across the internal resistance and the internal resistance.

In step S314, remaining time calculator 100 may determine the battery's open circuit voltage at the current time-step based on the updated SoC. Similar to the process described in step S302, remaining time calculator 100 may use the battery's open circuit voltage lookup table to determine the open-circuit voltage at the current time-step.

In step S316, remaining time calculator 100 may compute the battery's output voltage at the current time-step based on the voltage across the internal resistance determined in step S312 and the battery's open circuit voltage determined in step S314. The output voltage and may be computed according to:

Vₒᵤₜ=Vₒₚₑₙ−Vᵢₙₜ Eq. 4

where Vₒₚₑₙ is used to denote the open circuit voltage.

In step S318, remaining time calculator 100 may delay signals of the updated SoC and the battery's output voltage at the current time-step and feed them into the next iteration, i.e., steps S302 and S304 at the next time-step. This way, process 300 proceeds as the time progresses.

As illustrated by step 220, remaining time calculator 100 may repeat the iteration until the SoC of the battery reaches a predetermined level, e.g., 0%. Remaining time calculator may then integrate the time-steps to generate remaining time 7 of the battery.

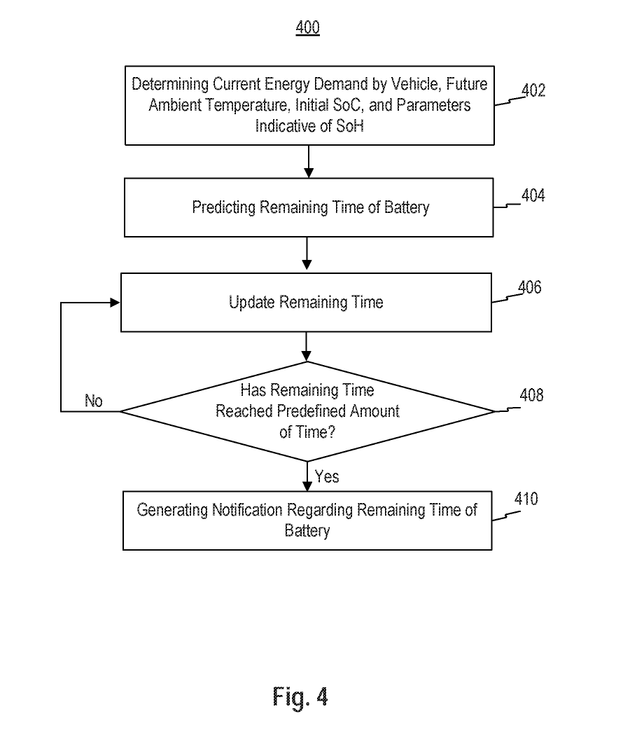

FIG. 4 is a flowchart of a notification method 400 for remaining time of a battery, according to an exemplary embodiment. For example, method 400 may be performed by remaining time calculator 100.

In step 402, remaining time calculator 100 may determine the power demand for the battery, the future ambient temperature of the battery, the initial SoC of the battery, and parameters indicating various aspects of the SoH of the battery.

Remaining time calculator 100 may determine the power demand based on the power required by the loads connected to the battery. In particular, when the vehicle is turned off, VMS 130 may be the only load that consumes the battery energy and thus the power demand is equal to the power required by VMS 130.

Remaining time calculator 100 may also determine the future ambient temperature of the battery in various methods. In one embodiment, remaining time calculator 100 may use the air temperature forecasted by weather data service 160 as the future ambient temperature. In another embodiment, remaining time calculator 100 may predict the ambient temperature based on historical weather data of the area where the battery is located, i.e., where the vehicle is used and/or parked. For example, remaining time calculator 100 may obtain the historical weather data from weather service 160 via network 180, and estimate future weather condition based on the historical weather data. Remaining time calculator 100 may then predict the ambient temperature based on the estimated weather condition. To perform the prediction process, remaining time calculator 100 may employ any suitable metrology model, temperature model, statistical model, vehicle model, etc.

The parameters indicative of the SoH may include, but are not limited to, the battery's self-discharge current, internal resistance, and capacity. Remaining time calculator 100 may determine the SoC and SoH itself using any suitable method known in the art. Alternatively, the SoC and SoH may be determined by BMS 120 and provided to remaining time calculator 100.

In step 404, remaining time calculator 100 may predict the remaining time for the initial SoC of the battery to drop to a predetermined level. For example, remaining time calculator 100 may predict the remaining time according to process 300 illustrated in FIG. 3.

Specifically, the drop of the SoC is attributable to the self-discharge and the power demand for the battery. Accordingly, remaining time calculator 100 may estimate the electric current flowing out of the battery, including the self-discharge current and the electric current drawing by the load(s), e.g., VMS 130. Remaining time calculator 100 may estimate the self-discharge current based on the predicted ambient temperature, the SoC of the battery, and the self-discharge characteristics (i.e., dependency of the self-discharge current on the ambient temperature and the SoC). Remaining time calculator 100 may estimate the electric current drawing from the load(s) based on the predicted ambient temperature, the SoC of the battery, the internal resistance of the battery, and the power required by the load(s).

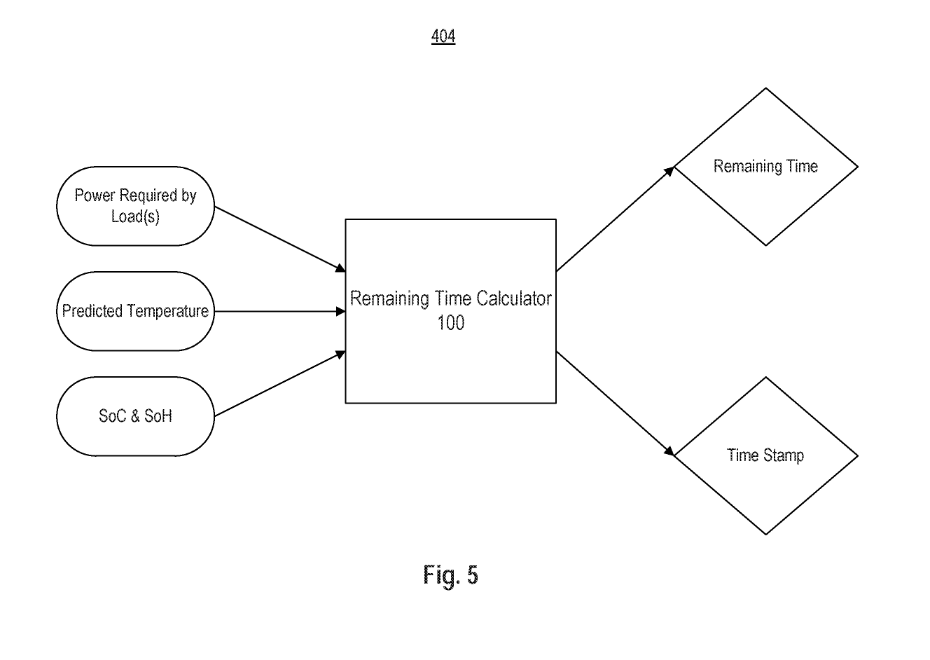

FIG. 5 is a schematic diagram illustrating an implementation of step 404 of method 400, according to an exemplary embodiment. Referring to FIG. 5, the input to remaining time calculator 100 may include the power required by the load(s), the predicted ambient temperature, the SoC, and SoH. After predicting the change of the SoC, remaining time calculator 100 may output the predicted remaining time for the SoC to drop to the predetermined level, e.g., 0%. Remaining time calculator 100 may also generate a timestamp indicating the point in time when the remaining time is predicted.

In step 406, remaining time calculator 100 may update the remaining time, to improve the accuracy of the remaining time. For example, if the actual ambient temperature deviates from the ambient temperature, remaining time calculator 100 may need to refine the predicted ambient temperate and update the remaining time based on the refined ambient temperature. Moreover, the actual power required by the load(s) may fluctuate and thus demand update of the remaining time. For example, an earlier prediction of the remaining time may be based on the assumption that the vehicle was turned off and the VMS 130 was the only load consuming power. However, if later the vehicle's security alarm system is triggered by an attempted break-in event or the vehicle is driven by the user, these developments change the power consumption by the load(s) and thus demand rerunning the prediction based on the changed vehicle condition.

In the disclosed embodiments, remaining time calculator 100 may regularly perform the updating according to a predetermined schedule, e.g., once a day. Remaining time calculator 100 may also initiate the updating step when certain conditions are detected. In one embodiment, when detecting that a user enters, via control panel 140 or mobile terminal 150, a command for updating the remaining time, remaining time calculator 100 may initiate the updating of the remaining time. In another embodiment, remaining time calculator 100 may update the remaining time when a user-specified requirement is satisfied. For example, since the performance of the battery depends on the ambient temperature, a user may specify that the remaining time be updated whenever the ambient temperature is above 40° C. or below −15° C. In yet another embodiment, remaining time calculator 100 may initiate the updating when it is detected that certain status of the vehicle has changed. For example, after detecting that the vehicle is turned on by a user, remaining time calculator 100 may update the remaining time.

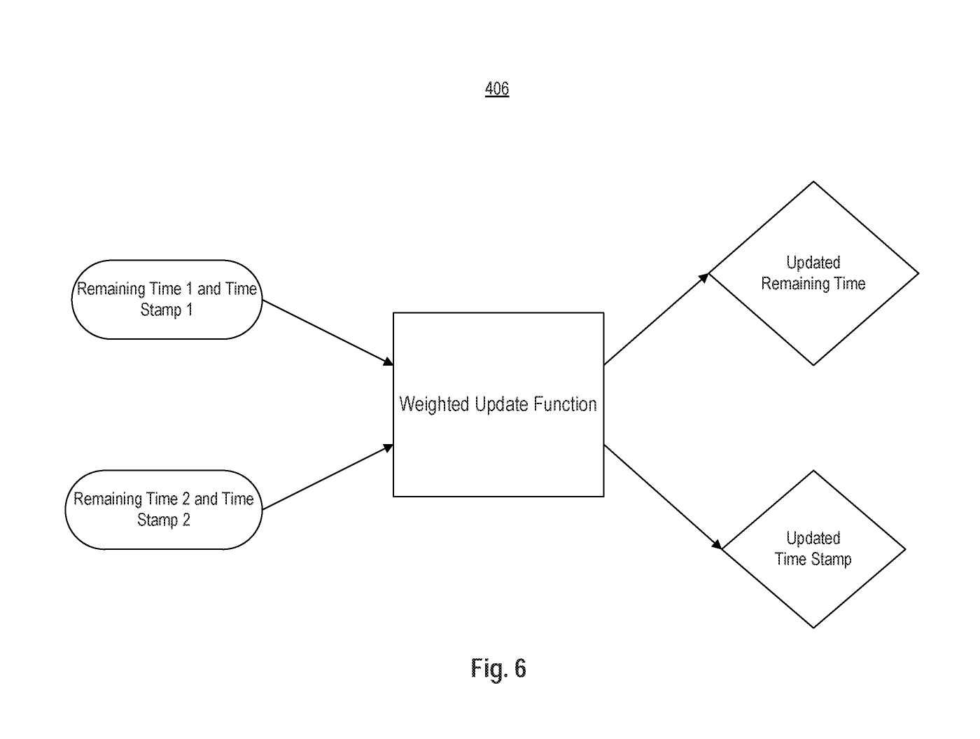

In some embodiments, remaining time calculator 100 may treat the most recently predicted remaining time as the updated remaining time. Alternatively, remaining time calculator 100 may generate the updated remaining time based on a weighted average of multiple remaining times predicted at different points in time. FIG. 6 is a schematic diagram illustrating an implementation of step 406 of method 400, according to an exemplary embodiment. Referring to FIG. 6, remaining time calculator 100 may predict a first remaining time and a second remaining time at different points in time. Remaining time calculator 100 may then use a weighted update function to generate the updated remaining time based on the first and second remaining times, and generate a timestamp indicating when the updated remaining time is generated for future reference. The weighted update function may be constructed based on any suitable prediction model. For example, the more recently predicted remaining time may be given a heavier weight in the weighted update function. As another example, the remaining time predicted immediately after the occurrence of a severe weather condition, e.g., thunderstorm, heavy rain, etc., may be given a heavier weight.

In step 408, remaining time calculator 100 may determine whether the remaining time reaches a predefined amount of time. If the remaining time reaches the predefined amount of time, method 400 proceeds to step 410. Otherwise, method 400 returns to step 406.

In the disclosed embodiments, the predefined amount of time may be specified by a user in the form of a number, such as parking the vehicle for 24 hours before the battery becomes empty; in the form of a condition, such as that the remaining energy in the battery is only enough for the vehicle to reach a nearby charging station; and/or in the hybrid form of both number and condition, such as parking the vehicle for 8 hours before the remaining energy in the battery drops to a level only enough for the vehicle to reach a nearby charging station.

For example, to determine the remaining energy in the battery that is just enough for the vehicle to reach a nearby charging station, remaining time calculator 100 may determine the location of the vehicle based on GPS coordinates provided by VMS 130, and then access vehicle charging station database 170 to retrieve location information of the charging stations in a predefined vicinity of the vehicle. Based on the locations of the charging stations, remaining time calculator 100 may determine the average distance from the vehicle to the charging stations or the distance to the nearest charging station, or a charging station of the user's preference. Remaining time calculator 100 may then determine an energy level in the battery that is enough for the vehicle to travel the average distance or reach the selected charging station.

In step 410, when the remaining time reaches the predefined amount of time, remaining time calculator 100 may generate a notification regarding the remaining time, for presentation to a user. The notification may include a message representing the remaining time, and/or an alert indicating whether the remaining time may cause issues to the vehicle. When the vehicle is turned on (e.g., in an idling mode or driving mode) and/or in a charging mode, the notification may be presented via control panel 140 or mobile terminal 150. When the vehicle is turned off and/or when the user is not in the vehicle, the notification may be presented to the user via mobile terminal 150. Control panel 140 and mobile terminal 150 may present the notification in various formats, including but not limited to numbers, texts, graphic icons, flashing lights, alarm sounds, etc.

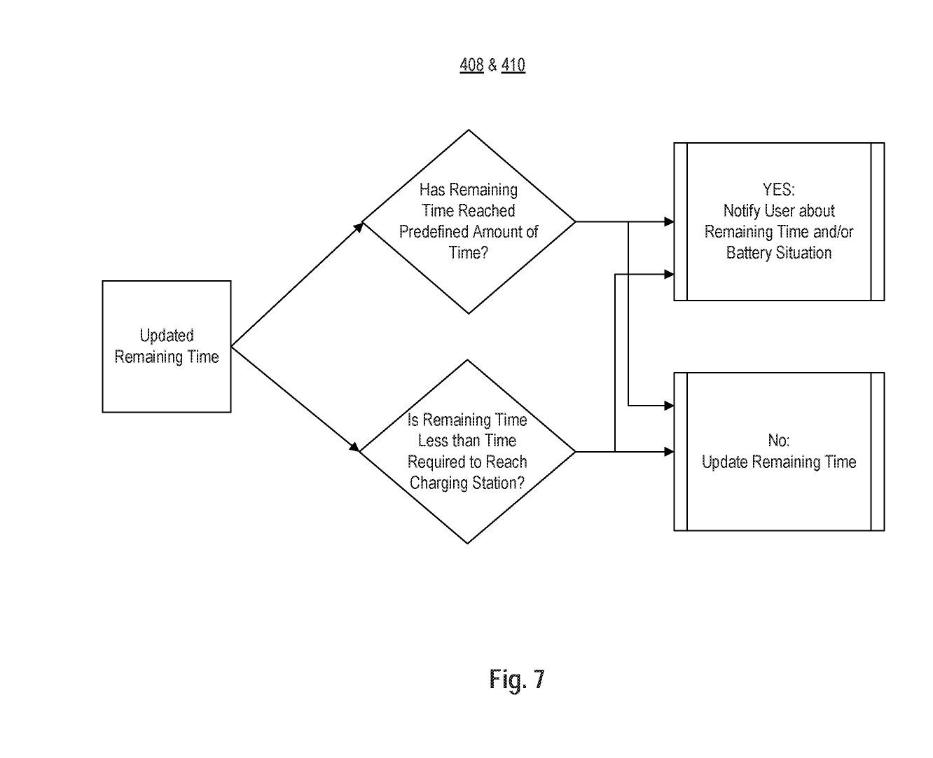

FIG. 7 is a schematic diagram illustrating an implementation of steps 408 and 410 of method 400, according to an exemplary embodiment. Referring to FIG. 7, after predicting and updating the remaining time, remaining time calculator 100 may determine whether the remaining reaches a predefined amount of time. If yes, remaining time calculator 100 may generate a notification about the remaining time and/or the corresponding battery situation. The notification may include information such as how much longer the user can park the vehicle without making the battery dead. If the remaining has not reached the predefined amount of time, remaining time calculator 100 may continue to update the remaining time (e.g., returning to step 406).

In some embodiments, in addition to warning a user about potential issues or risks associated with the remaining time of the battery, remaining time calculator 100 may also be configured to provide notifications when the remaining time indicates that the battery is already in a state lower than a minimum charge required to start or move to a charging station, so that a user can plan ahead for remedial measures. Still referring to FIG. 7, remaining time calculator 100 may determine whether the remaining time is less than an amount of time corresponding to the minimum energy required by the vehicle to reach a nearby charging stations (not shown in FIG. 4). If yes, remaining time calculator 100 may generate a notification informing the user that the vehicle no longer can move to any charging stations. This way, rather than being caught by a surprise when she wants to use the vehicle, the user may set an appointment to have the vehicle towed to a charging station or call a charging truck to recharge the battery on site.

Another aspect of the disclosure is directed to a non-transitory computer-readable medium storing instructions which, when executed, cause one or more processors to perform the methods, as discussed above. The computer-readable medium may include volatile or non-volatile, magnetic, semiconductor, tape, optical, removable, non-removable, or other types of computer-readable medium or computer-readable storage devices. For example, the computer-readable medium may be the storage unit or the memory module having the computer instructions stored thereon, as disclosed. In some embodiments, the computer-readable medium may be a disc or a flash drive having the computer instructions stored thereon.

It will be apparent to those skilled in the art that various modifications and variations can be made to the disclosed remote control system and related methods. Other embodiments will be apparent to those skilled in the art from consideration of the specification and practice of the disclosed remote control system and related methods. It is intended that the specification and examples be considered as exemplary only, with a true scope being indicated by the following claims and their equivalents.

What is claimed is:

1. A notification method for a battery, the method comprising:
predicting an ambient temperature of the battery;
determining a power demand for the battery;
determining a state of health (SoH) of the battery;
predicting a remaining time for a state of charge (SoC) of the battery to reach a predetermined level, based on the ambient temperature, the power demand, and the SoH; and
providing a notification regarding the remaining time.

2. The method of claim 1, wherein predicting the ambient temperature comprises:
acquiring historical weather data of an area where the battery is located;
estimating future weather condition based on the historical weather data; and
predicting the ambient temperature based on the future weather condition.

3. The method of claim 1, wherein the SoH comprises at least one of a capacity of the battery, an internal resistance of the battery, or self-discharge characteristics of the battery.

4. The method of claim 3, wherein predicting the remaining time comprises:
determining a current drawn from the battery;
determining an initial SoC of the battery; and
predicting the remaining time based on the current, the initial SoC, and the capacity of the battery.

5. The method of claim 4,
wherein the current drawn from the battery comprises a self-discharge current of the battery; and
wherein the method further comprises:
predicting the self-discharge current based on the initial SoC, the ambient temperature, and the self-discharge characteristics of the battery.

6. The method of claim 4,
wherein the current drawn from the battery comprises a current required by a load of the battery; and
wherein the method further comprises:
predicting the current required by the load based on the initial SoC, the ambient temperature, the internal resistance of the battery, and power required by the load.

7. The method of claim 1, wherein determining the remaining time further comprises:
determining that a condition has occurred; and
in response to the determination, updating the remaining time.

8. The method of claim 7, wherein the condition comprises at least one of:
receiving a user command for updating the remaining time;
determining that a user-specified requirement is satisfied; or
determining that a status of a device using the battery has changed.

9. The method of claim 7,
wherein the time to be updated is a first remaining time determined at a first point in time; and
wherein updating the remaining time comprises:
determining, at a second point in time, a second remaining time; and
computing an updated remaining time based on a weighted function of the first and second remaining time.

10. The method of claim 1, wherein the battery is used in a vehicle.

11. The method of claim 10, wherein the power demand for the battery comprises power required by a vehicle monitoring system of the vehicle.

12. The method of claim 10, wherein the notification indicates whether the battery has enough energy for the vehicle to reach a charging station.

13. The method of claim 12, wherein:
when determining that the remaining time reaches a preset time duration or corresponds to a minimum energy level of the battery required by the vehicle to reach the charging station, presenting the notification via a user interface.

14. The method of claim 12, further comprising:
acquiring location information of one or more charging stations;
determining an average distance from the vehicle to the charging stations; and
determining the minimum energy level based on the average distance.

15. A notification system of for a battery, the system comprising:
a memory storing instructions; and
a processor configured to execute the instructions to:
predict an ambient temperature of the battery;
determine a power demand for the battery;
determine a state of health (SoH) of the battery;
predict a remaining time for a state of charge (SoC) of the battery to reach a predetermined level, based on the ambient temperature, the power demand, and the SoH; and
provide the notification regarding the remaining time.

16. The system of claim 15, wherein the processor is further configured to execute the instructions to:
acquire historical weather data of an area where the battery is located;
estimate future weather condition based on the historical weather data; and
predict the ambient temperature based on the future weather condition.

17. The system of claim 15, wherein the processor is further configured to execute the instructions to:
determine a current drawn from the battery;
determine an initial SoC of the battery; and
predict the remaining time based on the current, the initial SoC, and a capacity of the battery.

18. The system of claim 17,
wherein the current drawn from the battery comprises a self-discharge current of the battery; and
wherein the processor is further configured to execute the instructions to:
predict the self-discharge current based on the initial SoC, the ambient temperature, and self-discharge characteristics of the battery.

19. The system of claim 17,
wherein the current drawn from the battery comprises a current required by a load of the battery; and
wherein the processor is further configured to execute the instructions to:
predict the current required by the load based on the initial SoC, the ambient temperature, an internal resistance of the battery, and power required by the load.

20. A vehicle, comprising:
a battery;
a battery management system configured to determine a state of charge (SoC) and a state of health (SoH) of the battery; and
a controller configured to:
predict an ambient temperature of the battery
determine power required by the vehicle;
predict a remaining time for the SoC of the battery to reach a predetermined level, based on the ambient temperature, the power required by the vehicle, and the SoH; and
provide the notification regarding the remaining time.
